(19) United States
(12) Patent Application Publication
(10) Pub. No.: US 2024/0295428 A1
(43) Pub. Date: Sep. 5, 2024

(54) SYSTEMS AND METHODS FOR MEASURING STRUCTURAL ELEMENT DEFLECTIONS

(71) Applicant: MachineSense, LLC, Baltimore, MD (US)

(72) Inventors: Biplab Pal, Ellicott City, MD (US); Conrad BESSEMER, Millersville, MD (US); Joy BAGCHI, Thakurnagar (IN); Bibhu BISWAL, Odisha (IN)

(73) Assignee: MachineSense, LLC, Baltimore, MD (US)

(21) Appl. No.: 18/479,662

(22) Filed: Oct. 2, 2023

Related U.S. Application Data
(63) Continuation of application No. 16/780,150, filed on Feb. 3, 2020, now abandoned.
Application No. 16/780,150 is a continuation-in-part of application No. 16/715,116, filed on Dec. 16, 2019.
(60) Provisional application No. 62/866,299, filed on Jun. 25, 2019.
(60) Provisional application No. 62/800,864, filed on Feb. 4, 2019.
(60) Provisional application No. 62/861,451, filed on Jun. 14, 2019.

(51) Int. Cl. G01G 7/02; G01G 19/03; G01M 5/00; G01R 33/02; G06V 10/764; G06V 10/82; G06V 20/52; G06V 20/62; G08G 1/01; G08G 1/042

(52) U.S. Cl. CPC G01G 7/02; G01G 19/03; G01M 5/0008; G01R 33/0206; G06V 10/764; G06V 10/82; G06V 20/52; G08G 1/0116; G08G 1/042; G06V 20/625

(57) ABSTRACT

System and apparatus for monitoring a structural element includes a magnetometer capable of being mounted on the structural element, a magnet capable of being mounted on a surface adjacent the structural element so that the magnetometer is positioned within a magnetic field of the magnet; and a computing device capable of being communicatively coupled to the magnetometer, the magnetometer measuring characteristics of the magnetic field of the magnet, the computing device determining deflection of the structural element based on the measured characteristics of the magnetic field and a mathematical relationship between characteristics of the magnetic field and position of the magnetometer in relation to the magnet.

### CROSS REFERENCE TO RELATED PATENT APPLICATIONS

This patent application is a 35 USC 120 continuation of U.S. patent application Ser. No. 16/780,150, filed 3 Feb. 2020, entitled “Systems and Methods for Measuring Structural Element Deflections”, and published as U.S. Patent Publication No.: US 2020-0249118 A1, the contents of which are incorporated herein in their entirety; the priority is claimed under 35 USC 120.

The '150 patent application is a 35 USC 120 continuation of, and claims the benefit of the filing date of, U.S. provisional patent application Ser. No. 62/861,451, entitled “Dynamic Measurement of 3 Axis Deflection for Structural Element Using a Magnet and Magnetometer,” filed 14 Jun. 2019, the contents of which are incorporated by reference herein in their entirety; priority is claimed under 35 USC 120.

The '150 patent application is also a 35 USC 120 continuation of, and claims the benefit of the filing date of, U.S. provisional patent application Ser. No. 62/800,864 entitled “Combination IOT System and Video Analytics to Identify Illegally Heavy Loaded Vehicle on the Bridge and the Resulting Deflection of the Bridge Structure,” filed 4 Feb. 2019, the contents of which are incorporated herein in their entirety; the priority is claimed under 35 USC 120.

The '150 patent application is also a 35 USC 120 continuation of, and claims the benefit of the filing date of, U.S. provisional patent application Ser. No. 62/866,299 entitled “Dynamic Measurement of 3 Axis Deflection For Structural Health Monitoring Using a Magnet and Magnetometer,” filed 25 Jun. 2019, the contents of which are incorporated herein in their entirety; the priority is claimed under 35 USC 120.

The '150 patent application is also a 35 USC 120 continuation-in-part of U.S. utility patent application Ser. No. 16/715,116, entitled “Systems and Methods for Measuring Structural Element Deflections” filed 16 Dec. 2019 and published as U.S. Patent Publication No.: US 2020-0408633 A1; the contents of which are incorporated by reference in their entirety; the priority thereof is claimed under 35 USC 120.

### STATEMENT REGARDING FEDERALLY SPONSORED RESEARCH OR DEVELOPMENT

Not applicable-this invention was conceived and developed entirely using private source funding; this patent application is being filed and paid for entirely by private source funding.

### DESCRIPTION OF THE PRIOR ART

Structural health monitoring involves monitoring the condition of structural systems such as bridges, roadbeds, flyovers, dams, skyscrapers, etc. Condition monitoring is the process of monitoring certain parameters of a system for significant variations that can indicate a need for some type of action, such as an alarm or maintenance notification. When applied to structural systems, condition monitoring can facilitate implementation of maintenance and other actions that reduce the potential for structural degradation and failure, and eliminate monetary costs and dangers that can result therefrom.

Condition monitoring of structures and structural systems typically includes monitoring vibrational signatures of individual structural elements using, for example, accelerometers; signatures resulting from laser scanning; and signatures resulting from radio-frequency identification. Measuring three-axis, i.e. three-dimensional, deflection of structural elements is important when assessing health of a structure. Such deflection can occur when a dynamic load is applied to the structure, such as when a truck drives across a bridge. Measurement of the maximum deflection of structural elements, and the dynamic response of the structure as it retracts from the deflection are critical, and are of prime importance when monitoring structural integrity.

Structural health monitoring is gaining in importance because it can improve human safety and reduce maintenance costs. One of the challenges in structural health monitoring, however, is in performing the requisite analyses, and generating actionable information in real-time. This challenge exists due, in general, to the absence of infrastructure facilities capable of providing the requisite data analyses; the costs of conducting calibration and empirical data gathering on-site at the structure; and the lack of on-site data-processing capabilities.

Many methods for measuring deflection of structural members currently exist. These methods include, for example, laser scanning technology, the dial indicator method, and the total station method. Such methods, however, can be costly and have limitations. For example, the results of the total station method can be affected by temperature changes and humidity. Also, most of these methods are limited to determining single-axis axis deflection of a structural member, and many of the methods cannot be adapted to dynamic monitoring, i.e. gathering data, analyzing the data, and generating actionable information on a real-time or near real-time basis.

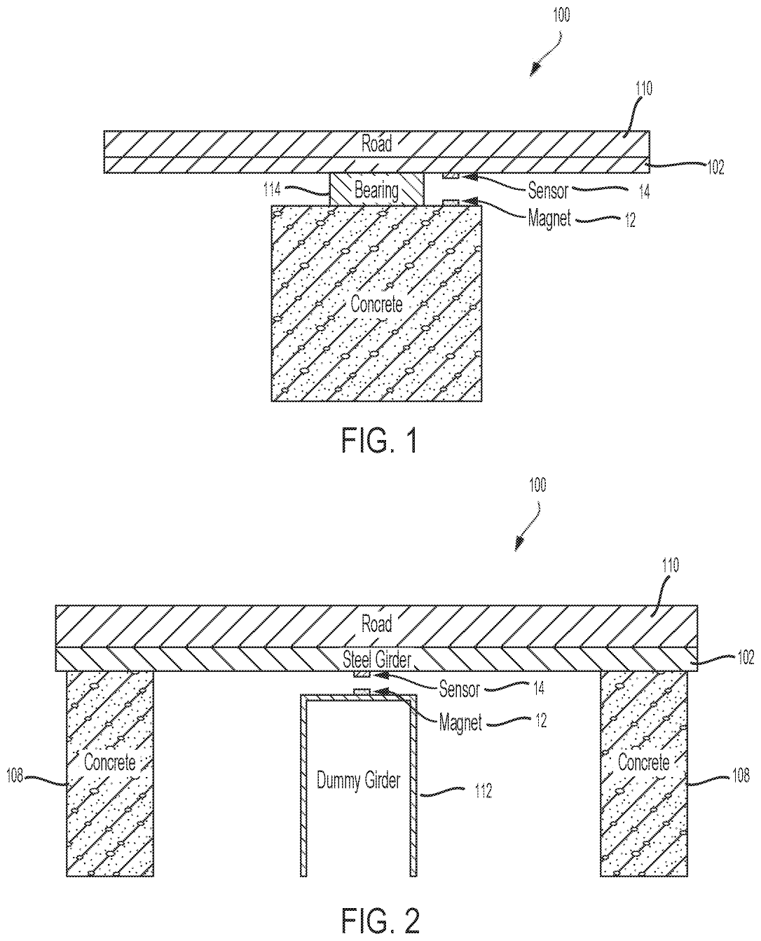

Many bridges can benefit from structural health monitoring due to their relative complexity, exposure to the elements, heavy traffic volume, high maintenance costs, etc. Structural deflection can be monitored at many locations on a bridge, such as at mid-span, girder joints, beam joints, and concrete joints. For example, FIGS. 1, 2, and 11 through 14 of this application schematically depict a bridge 100. The bridge 100 includes two or more girders 102. Each girder 102 is a large, horizontally-oriented beam, or a compound structure, mounted on preferably concrete piers 108 partially embedded in the ground. The girder 102 spans the space between two or more of piers 108, and in combination with one or more other girders 102 supports a road deck 110 of bridge 100. The upper exterior surface of road deck 110 provides a roadway for vehicular traffic crossing bridge 100.

FIG. 11 depicts a girder 102 of bridge 100 experiencing maximum deflection at mid-span in response to vehicular traffic on road deck 110. As can be seen in FIG. 11, this deflection occurs primarily in one direction, namely vertically. Thus, when monitoring the health of the bridge at mid-span, measurement of vertical deflection alone usually is sufficient.

At other locations on the bridge, however, the presence of faults may result in horizontal structural deflection, as well as vertical structural deflection. Horizontal deflection is more prominent during active/dynamic loading than during static loading, due primarily to the action and reaction forces produced by a dynamic load, as can be seen in the side view of the bridge in FIG. 14, and the top view in FIG. 13.

If a joint is located at or near a curved portion of the bridge roadway, the centrifugal force generated by the moving vehicles can cause structural deflection in three axes. Vertical deflection is due primarily to load exerted by the vehicle; while deflection along the two horizontal axes is primarily due to centrifugal forces, as shown in FIG. 14.

Thus, measuring structural deflection in three dimensions can be critical to conducting effective structural health monitoring of bridges and other structures.

### SUMMARY OF THE INVENTION

In a principal one of its aspects, this invention relates generally to systems and methods for monitoring the health of structural systems by determining the deflection of individual structural members of the structural systems preferably using a magnet and a magnetometer.

In the literature magnetic forces are usually described as being magnetic fields in which the magnetic forces are characterized as vector quantities. Magnetic force is measured in “tesla” or gauss. Currently available sensors measure the magnetic field strength in microtesla or 0.0001% of 1 “tesla”.

In this patent application the terms “sensor” and “magnetometer” are used largely interchangeably, as is clear from their context. “Sensor” is to be understood as a device for measuring a 3 axis magnetic field in microtesla and providing a signal, in digital form, indicative of the vector value of the magnetic field. “Magnetometer” is similarly to be understood as a device for measuring a 3 axis magnetic field in microtesla and providing a signal in digital form, indicative of the measured value of the field. The preferred “sensor” and “magnetometer” as addressed in this application provide digital signals of magnetic field measured in three different directions simultaneously, with the directions corresponding to a conventional orthogonal x, y, z coordinate system.

Sometimes herein the magnetometer is referred to as a “tri-axial” magnetometer, meaning that the digital signal provided by the magnetometer (or the “sensor” if the context indicates) has three components, one each indicating the measured value of gauss along each of the x, y, and z axes of a conventional orthogonal x, y, and z coordinate system whose origin is the origin of a closely placed magnet creating a corresponding magnetic field pattern with high field gradient, which means there is a high differential change of the field with respect to a small change in co-ordinates. The resulting magnetic field is made to lack rotational and mirror symmetry so that the magnetic field as a function of position variable (x,y,z) yields a unique transformation for each position.

Herein there is some discussion of calibrating or otherwise using the magnetometer (or “sensor”) with respect to just the x and y axes, i.e. in a two dimensional application. From context it will be understood that in such cases, a “tri-axial” magnetometer may be used, with the output signal for the magnetic field measured in the “z” direction being ignored. In other instances and essentially throughout the application from context it will be understood that “magnetometer” and “sensor” denote devices measuring field in microtesla and providing digital signals indicative of the measured values of the field in three directions corresponding to a conventional orthogonal x, y, z coordinate system. These tri-axial magnetometers are preferably configured to furnish output digital signals wirelessly to some other output device, using one or more of the communication protocols noted herein.

In accordance with various aspects of the inventive concepts disclosed herein, systems for monitoring a structural element include a magnetometer capable of being mounted on the structural element, and a magnet capable of being mounted on a surface adjacent the structural element so that the magnetometer is positioned within the effective magnetic field of the magnet. The systems also include a computing device capable of being communicatively coupled to the magnetometer. The magnetometer is configured to measure characteristics of the magnetic field of the magnet. The computing device determines the position of the magnetometer in relation to the magnet based on the measured characteristics of the magnetic field using a stack or combination of signal processing and at least one suitable machine learning algorithm.

In another one of its aspects this invention provides apparatus for detecting overweight vehicles and resulting damage to highway bridge structures therefrom. In this aspect of the invention, the apparatus includes a sensor for collecting dynamic vibration, gyroscopic and magnetometric data produced by a structural member in contact with the sensor. The apparatus further includes a system for receiving the collected data from the sensor and associating the time of collection of the data, therewith with the data, with the system including a data processing device computing, from the collected data deflection of the structure at an associated time. The apparatus still further includes a scanning device for capturing images of license plate numbers of vehicles crossing the bridge and a processor for time-correlating the images of license plates of vehicles crossing the bridge with the computed deflection of the bridge structure, to identify vehicles crossing the bridge and causing structural member deflection in excess of a pre-selected value.

In still another of its aspects this invention provides a method for detecting overweight vehicles causing damage to highway bridge structures as the vehicles traverse thereover, where the method incudes collecting dynamic vibration, gyroscopic and magnetometric data produced by a structural member of the bridge. The method proceeds by associating the time of collection of the data with the data itself. The method further proceeds by computing, from the collected data, deflection of the structural member at the associated time. The method further proceeds by capturing images of license plate numbers of vehicles crossing the bridge and then time-correlating the images of the license plates of the vehicles crossing the bridge with the computed deflection of the bridge structure to identify vehicles crossing the bridge and causing bridge structural member deflection in excess of a pre-selected allowable value.

In yet still another one of its aspects this invention provides a method for measuring structural deflection, where the method commences with positioning a wireless magnetometer on a portion of a structure of which the deflection is to be measured. The method proceeds by fixedly positioning a magnet within effective range of the magnetometer and sufficiently close to the structural portion of interest that the structural portion of interest is within the effective magnetic field of the magnet. The method proceeds by sensing a magnetic field vector with the magnetometer, as the portion of the structure of interest deflects. The method dynamically provides the sensed magnetic field vector position to a computing device, which is preferably an edge cloud computing device, as the portion of the structure deflects. The method proceeds by computing, as deflection information, the position of the portion of the structure for which deflection is to be measured from the dynamically-provided magnetic field vector position via an algorithm executed by the preferable edge cloud computing device.

The structural deflection to be measured may be vertical deflection, in which case the method proceeds by positioning the magnetometer and the magnet by vertically aligning the magnetometer with the magnet.

In still another variation of this aspect of the invention, the magnet may be positioned below the magnetometer.

In still yet another one of its aspects this invention provides a method for calibrating a sensing magnetometer to be used in conjunction with a magnet for detecting structural deflection. The method proceeds with moving a reference magnetometer through a pre-selected space to collect data of magnetic field strength of the magnet respecting a three-axis coordinate system. The method then proceeds by positioning the magnet such that the magnetic field no longer occupies the pre-selected space. The method further proceeds with moving the referenced magnetometer though the pre-selected space to collect data of the earth magnetic field respecting the three-axis coordinate system. Next, the method proceeds by subtracting the collected magnetic field data from new magnetic field data, which is collected as the magnetometer moves throughout the pre-selected space, to produce a data set containing only magnetic field components of the magnet measured by the reference magnetometer respecting the three-axis coordinate system.

For each of the three directions defined by the coordinate system, the method proceeds by applying the magnetic field components resulting from the data set to at least one neural network to produce a machine learning training set for the three position coordinates of the reference magnetometer relative to the magnet. The method further proceeds by positioning a sensing magnetometer at a selected position within the magnetic field of the magnet and thereafter measuring strength of the magnetic field at that position with the sensing magnetometer. The method then proceeds using the sensing magnetometer by measuring a training data set magnetic field strength at a positon corresponding to the selected magnetometer position within the magnet's magnetic field. The magnetic field strength sensed by the sensing magnetometer in the training data set is subtracted from the field strength sensed by the reference magnetometer to determine calibration of the sensing magnetometer relative to the reference magnetometer.

In another one of its aspects this invention provides a system for monitoring a structural element, comprising a magnetometer capable of being mounted on the structural element, a magnet capable of being mounted on a surface adjacent the structural element so that the magnetometer is positioned within a magnetic field of the magnet, and a computing device capable of being communicatively coupled to the magnetometer; wherein the magnetometer is configured to measure characteristics of the magnetic field of the magnet; and the computing device is configured to determine deflection of the structural element based on the measured characteristics of the magnetic field and a predetermined mathematical relationship between characteristics of the magnetic field and a position of the magnetometer in relation to the magnet. The computing device is desirably configured to determine a position of the magnetometer in relation to the magnet in three-dimensional space based on the measured characteristics of the magnetic field and the predetermined mathematical relationship between the characteristics of the magnetic field and a position of the magnetometer in relation to the magnet. The measured characteristics of the magnetic field include magnitude of the magnetic field in three orthogonal directions. The system may further include a gateway communicatively coupled to the magnetometer and configured to transmit an output of the magnetometer to the computing device over the Internet.

In another of its aspects this invention provides a method for monitoring a structural element by determining a mathematical relationship between characteristics of the magnetic field and a position of the magnetometer in relation to the magnet, mounting a magnetometer on the structural element, mounting a magnet on a surface adjacent the structural element so that the magnetometer is positioned within a magnetic field of the magnet, measuring characteristics of the magnetic field of the magnet, and determining a deflection of the magnetometer in relation to the magnet based on the measured characteristics of the magnetic field and the mathematical relationship between the characteristics of the magnetic field and a position of the magnetometer in relation to the magnet.

In yet another one of its aspects this invention provides a method for measuring structural deflection by positioning a wireless magnetometer on a portion of a structure where deflection is to be measured, fixedly positioning a magnet within wireless communication range of the magnetometer and sufficiently close to the structure portion of interest that the structure portion of interest is within the magnetic field of the magnet, sensing a magnetic field vector with the magnetometer as the portion of the structure deflects, dynamically providing the sensed magnetic field vector position to an edge cloud computing device as the portion of the structure deflects, extracting as deflection information the position of the portion of the structure for which deflection is to be measured from the dynamically provided magnetic field vector position via an algorithm executed by the edge cloud computing device, the algorithm being based on a predetermined mathematical relationship between characteristics of the magnetic field and a position of the magnetometer in relation to the magnet, and transmitting the deflection information from the edge cloud computing device to a user.

In yet still another one of it aspects this invention provides a method for measuring structural deflection by positioning a wireless magnetometer on the portion of a structure where deflection is to be measured, fixedly positioning a magnet within wireless communication range of the magnetometer and sufficiently close to the structure portion of interest that the structure portion of interest is within the magnetic field of the magnet, sensing a magnetic field vector with the magnetometer as the portion of the structure deflects, dynamically providing the sensed magnetic field vector position to an edge cloud computing device as the portion of the structure deflects, extracting as deflection information the position of the portion of the structure for which deflection is to be measured from the dynamically provided magnetic field vector position via an algorithm executed by the edge cloud computing device, the algorithm being based on a predetermined mathematical relationship between characteristics of the magnetic field and a position of the magnetometer in relation to the magnet, and transmitting the deflection information from the edge cloud computing device to a user.

In another one of its aspects this invention provides methods for detecting overweight vehicles and resulting damage to highway bridge structures therefrom, where the methods include collecting dynamic vibration, gyroscopic and magnetometric data experienced by a structural member; using a data processing device for associating the time of collection of the data with the data from the data indicating deflection of the structural member at an associated time; capturing digital images of license plates of vehicles crossing the bridge; and time correlating the images of license plates of vehicles crossing the bridge with computed deflection of the structure to identify vehicles crossing the bridge and causing structural member deflection in excess of a preselected value.

In still another one of its aspects this invention provides apparatus for detecting overweight vehicles and resulting damage to highway bridge structures therefrom, where the apparatus includes a sensor for collecting dynamic vibration, gyroscopic and magnetometric data experienced by a structural member contacted by the sensor, a system receiving the data from the sensor and associating the time of collection of the data therewith, the system including a data processing device for associating the time of collection of the data with the data and from the data computing deflection of the structural member at the associated time, a detector for capturing images of license plates of vehicles crossing the bridge, and a processor for time correlating the images of license plates of vehicles crossing the bridge with the computed deflection of the structure to identify vehicles crossing the bridge and causing structural member deflection in excess of a preselected value.

The following description is merely exemplary in nature and is not intended to limit the described embodiments of the invention or uses of the described embodiments. As used herein, the words “exemplary” and “illustrative” mean “serving as an example, instance, or for illustration.” Any implementation or embodiment or abstract disclosed herein as being “exemplary” or “illustrative” is not necessarily to be construed as preferred or advantageous over other implementations, aspects, or embodiments. All of the implementations or embodiments described in the detailed description are exemplary implementations and embodiments provided to enable persons of skill in the art to make and to use the implementations and embodiments as disclosed below, to otherwise practice the invention, and are not intended to limit the scope of the invention, which is defined by the claims.

Furthermore, by this disclosure, there is no intention on the part of the Applicant to be bound by any express or implied theory presented in the preceding, including but not limited to the summary of the invention or the description of the prior art, or in the following description of the invention. It is to be understood that the specific implementations, devices, processes, aspects, and the like illustrated in the attached drawings and described in the following portion of the application, usually referred to as the “specification,” are simply exemplary embodiments of the inventive concepts defined in the claims. Accordingly, specific dimensions and other physical characteristics relating to the embodiments disclosed herein are not to be considered as limiting as respecting the invention unless the claims or the specification expressly state otherwise.

DESCRIPTION OF THE DRAWINGS

FIG. 1 is a schematic drawing of an apparatus for monitoring health of a bearing positioned at mid-span of a bridge, in accordance with aspects of the invention.

FIG. 2 is a schematic illustration of an apparatus for monitoring health of a support girder in a bridge, in accordance with aspects of the invention.

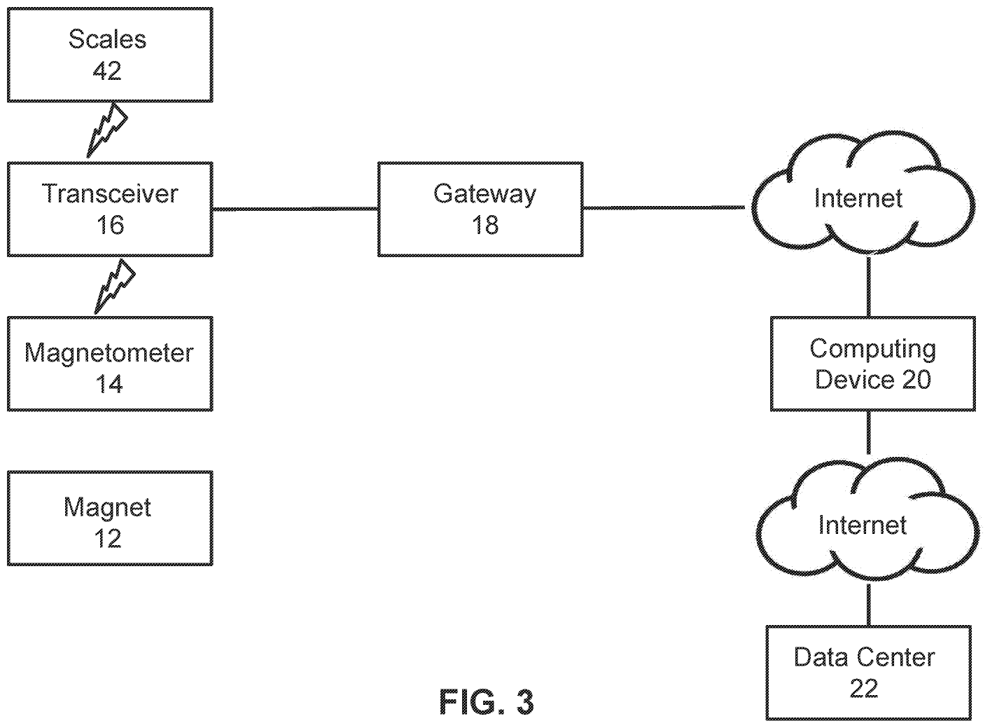

FIG. 3 is a schematic block diagram of certain mechanical and electrical components which may be used in the apparatus illustrated in FIGS. 1 and 2.

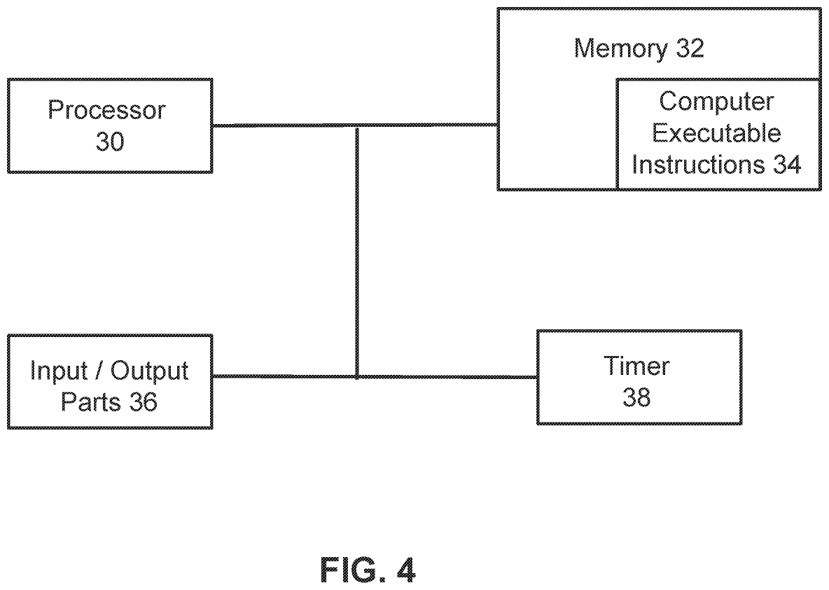

FIG. 4 is a schematic block diagram of a computing device portion of apparatus illustrated in FIG. 3, in accordance with aspects of the invention.

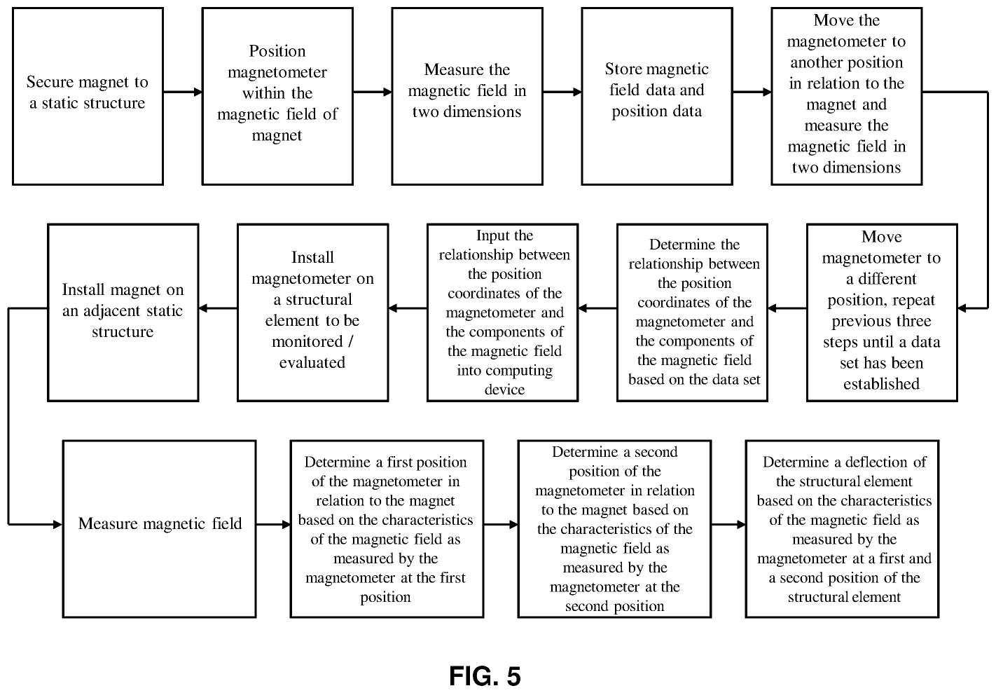

FIG. 5 is a flowchart depicting use of apparatus such as shown in FIGS. 1 and 2 to conduct structural health monitoring, in accordance with aspects of the invention.

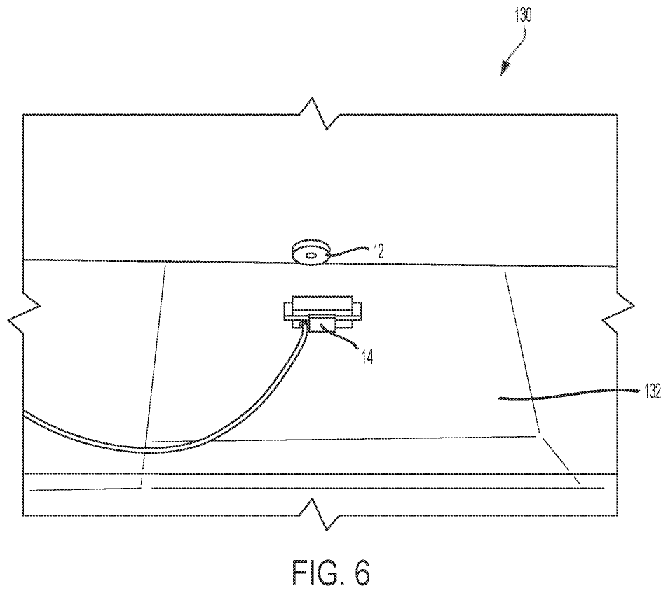

FIG. 6 is a schematic illustration of a portion of apparatus for performing two-axis structural deflection measurement in an experimental environment, in accordance with aspects of the invention.

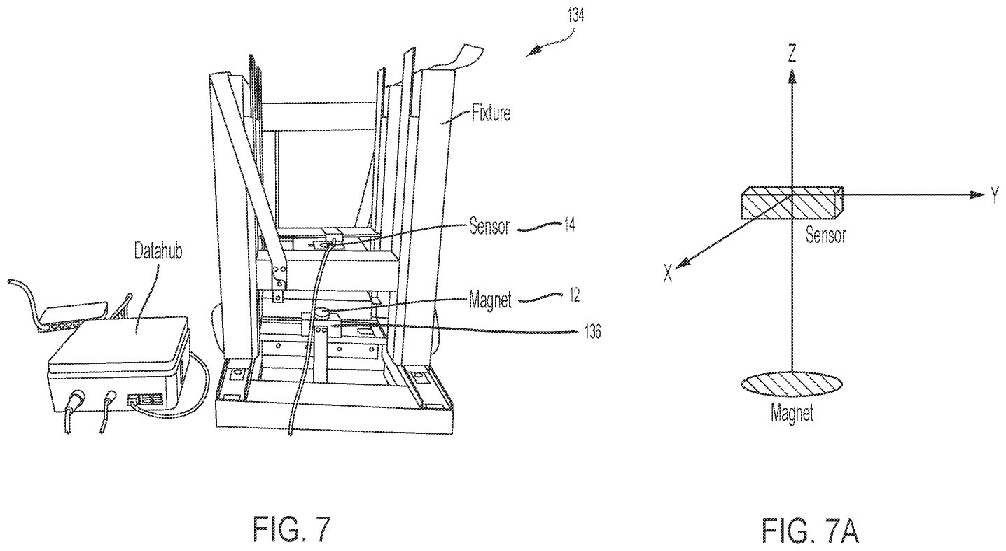

FIG. 7 is a schematic illustration of apparatus for performing three-axis structural deflection measurement in an experimental environment, in accordance with aspects of the invention.

FIG. 7A schematically depicts a three axis coordinate system with a wireless magnetometer at the origin and a magnet spaced therefrom on the negative z axis, in accordance with aspects of the invention.

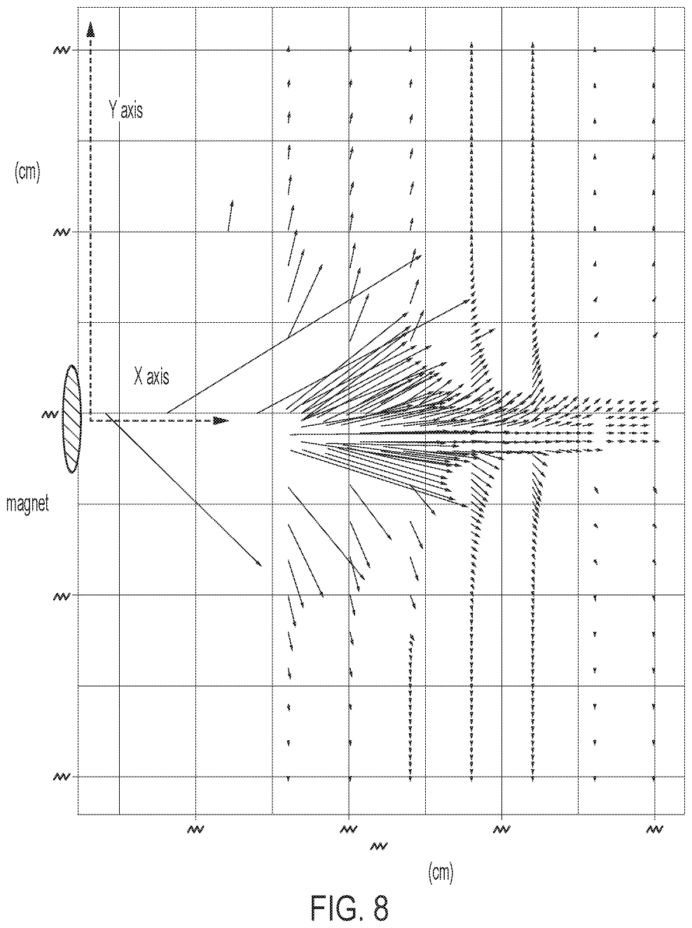

FIG. 8 is a plot of a magnetic field in an x-y plane, as measured in accordance with aspects of the invention, by apparatus shown in FIG. 6.

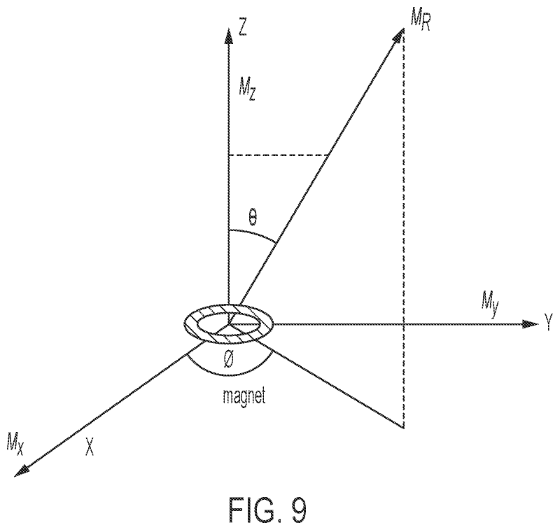

FIG. 9 is a plot of a magnetic field in an x-y plane where the magnetic field results from travel of a vehicle over a bridge.

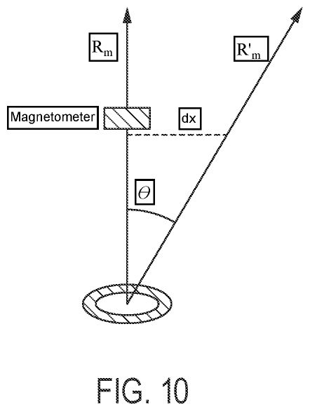

FIG. 10 is a plot schematically showing predicted and actual values of a magnetic field along the x-axis of a three axis coordinate system, as determined by a sensor.

FIG. 11 is a schematic side view of a bridge carrying a car showing vertical deflection of abridge roadway support in response to vertical loading results for the car.

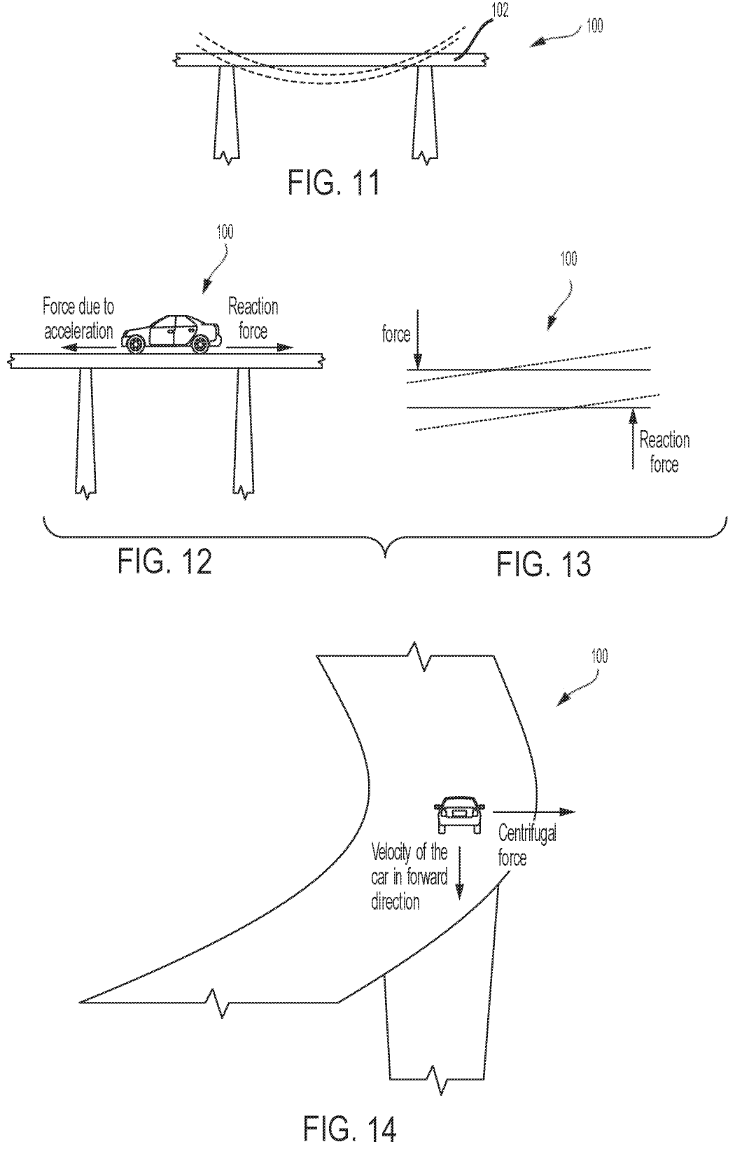

FIGS. 12 and 13 are schematic top views of deflection of the bridge of FIG. 11, where the deflection is transverse to direction of travel of the car.

FIG. 14 is a schematic illustration of deflection of the bridge of FIG. 11, where the deflection is tangential to direction of travel of the car.

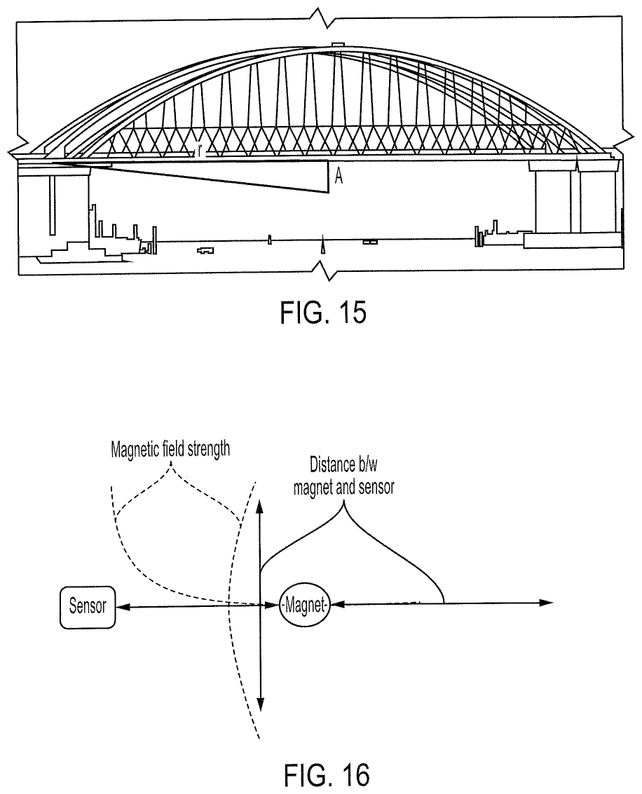

FIG. 15 is an artist's rendition of a bridge with vectors illustrating deflection of the center of the bridge, between two joints supporting the bridge structure.

FIG. 16 is a plot of distribution of magnetic field strength as a function of distance as sensed by a sensor, for a magnetic field produced by a magnet, as illustrated in FIG. 16.

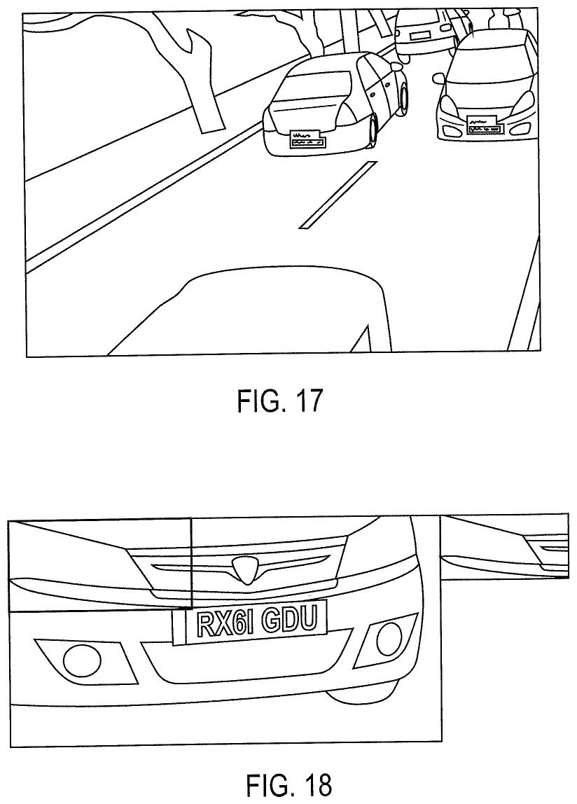

FIG. 17 is an illustration of a sample frame from a video showing moving vehicles and portions of images showing license plates of the moving vehicles.

FIG. 18 is an exemplary input image showing a sliding window on various scales, for scanning a license plate; on the right is the input frame a neural network sees, whereas the left of FIG. 18 shows a window in the context of the original exemplary input image.

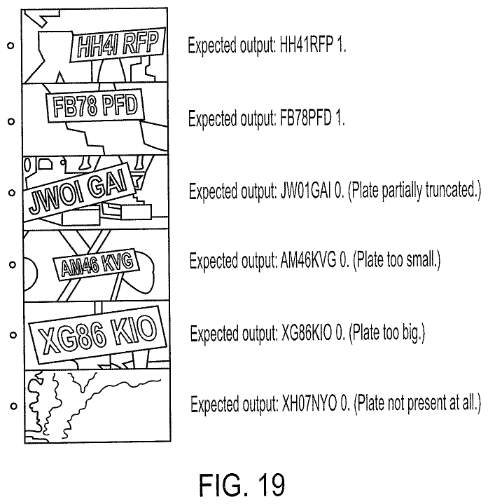

FIG. 19 is a drawing of a collection of images of license plates used for training a neural network for license plate number detection.

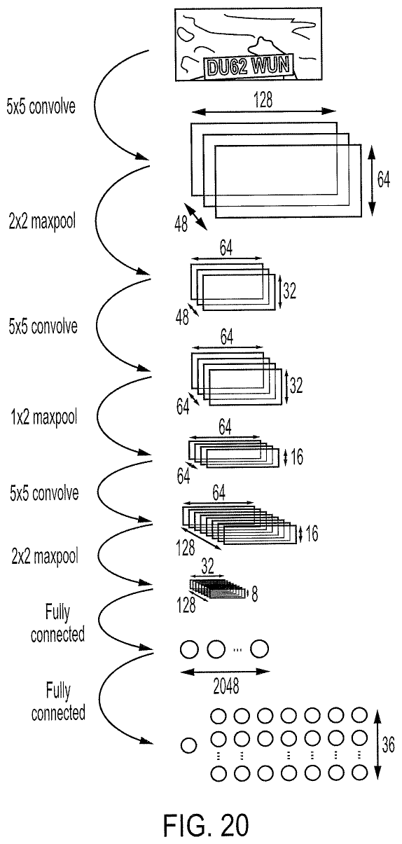

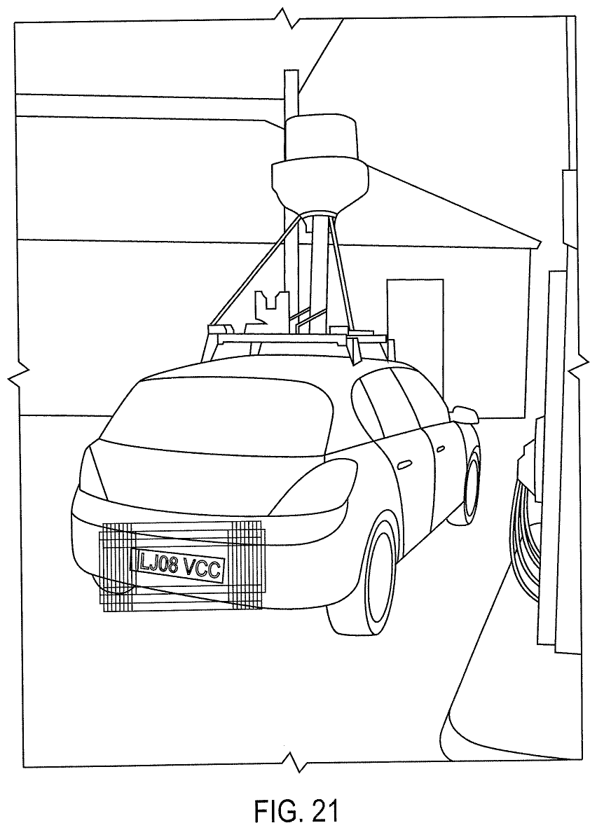

FIG. 20 is a schematic representation of network architecture of a learning engine trained to detect vehicle license plate numbers.

FIG. 21 is a drawing schematically illustrating a vehicle with a detected license plate number within a bounding box, for input to a neural network.

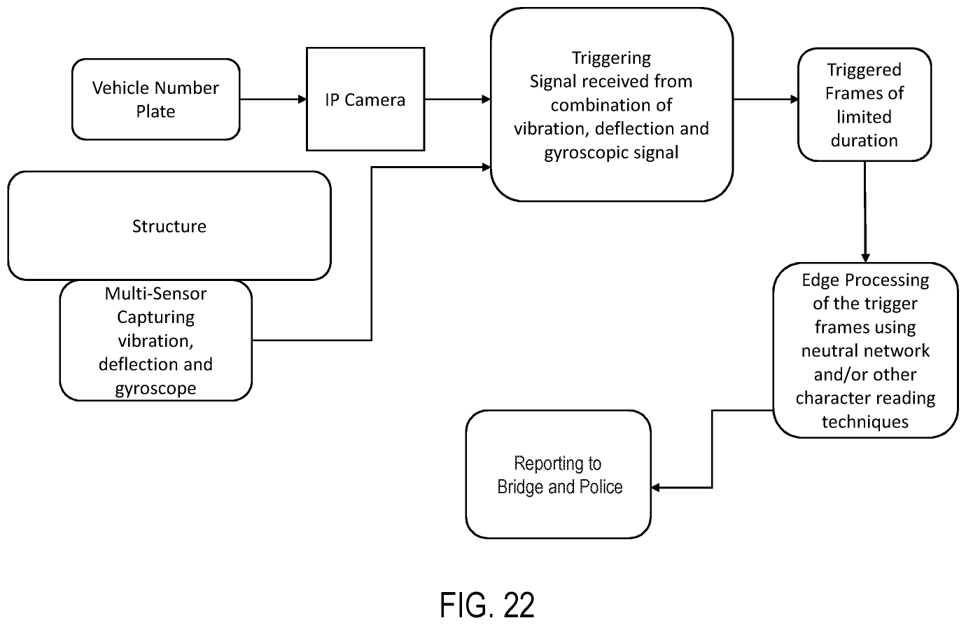

FIG. 22 is a schematic block diagram depicting a method of the invention for detecting overweight vehicles passing traveling on a bridge or other structure and using the detected information for traffic enforcement and the like.

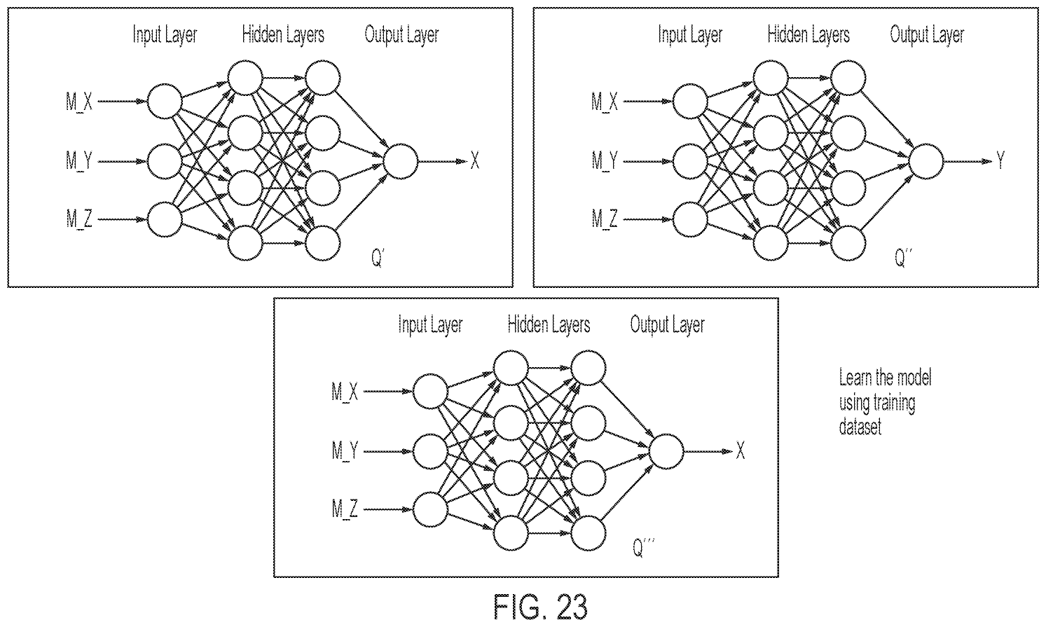

FIG. 23 is a schematic representation of a neural network suitable for use in practicing aspects of the invention.

### DESCRIPTION OF THE INVENTION

The inventive concepts are described with reference to the accompanying figures. The figures are not drawn to scale but do illustrate the inventive concepts. The figures do not limit the scope of the disclosure.

Several aspects of the inventive concepts embodied in the invention are described below with reference to exemplary applications for illustration. Numerous specific details, relationships, and methods are set forth to provide a full understanding of the inventive concepts. One having skill in the relevant art, however, will readily recognize that the inventive concepts can be practiced without one or more of the specific details or with other methods. In other instances, well-known structures or operations are not shown in detail, to avoid obscuring the inventive concepts.

In a preferred one of its aspects this invention provides systems and methods are provided for determining the deflection of structural elements. The structural elements can be components of bridge 100 depicted in FIGS. 1, 2, and 11 through 14. This particular application is disclosed for illustrative purposes only; the inventive concepts can be applied to other types of structures.

FIG. 1 depicts an embodiment of the invention in the form of a system. The system comprises a magnet 12, and a magnetic field sensor in the form of a magnetometer 14. Magnetometer 14 is installed on a structural element of bridge 100. Specifically, FIG. 1 schematically depicts magnetometer 14 installed on a roadway (or railway) support girder 102 of bridge 100. This particular application of the system is described for illustrative purposes only; the system can be used to measure the deflection of structural elements other than girder 102. FIG. 5 is a flowchart depicting use of the system to conduct structural health monitoring of bridge 100 or some other structural system.

As can be seen in FIG. 1, magnetometer 14 is installed on the underside of girder 102, desirably close to or even at the approximate horizontal mid-point of girder 102. Magnetometer 14 is positioned beneath girder 102 to avoid interfering with traffic on the roadway of bridge 100. The mid-span of girder 102 is the most heavily loaded portion of girder 102. FIG. 11 shows how girder 102 experiences maximum deflection at its horizontal mid-point in response to vehicular traffic on road deck 110. Thus, a girder at its horizontal mid-point, commonly a referred to as “mid-span,” is particularly vulnerable to cracking, deformation, and other damage, making it important to monitor the condition of girder 102 at that location.

Magnetometer 14 is secured to girder 102, so that magnetometer 14 undergoes the same deflection as girder 102 when girder 102 deflects under loading induced by vehicular traffic. Magnet 12 is mounted on a stationary structure, i.e. on a structure that does not move substantially in relation to the ground as girder 102 deflects. For example, as shown in FIG. 2 magnet 12 can be secured to a “dummy girder” 112 positioned beneath girder 102 and anchored to the ground. Dummy girder 112 is configured so that magnetometer 14 is positioned within the three-dimensional magnetic field of magnet 12, but does not contact girder 102 or any other portion of bridge 100. Thus, when girder 102 deflects, relative movement between magnetometer 14 and magnet 12 substantially matches the relative movement of the mid-span of girder 102 with respect to the earth.

The magnetic field produced by magnet 12 acts as a fixed reference frame against which three-dimensional deflection of girder 102 in relation to the ground or another structure can be quantified. In particular, the relative movement between magnet 12 and magnetometer 14 affects the characteristics of the magnetic field to which magnetometer 14 is subjected. In practice of the invention the relationship between the characteristics of the magnetic field as measured by magnetometer 14, and the position of magnetometer 14 in relation to magnet 12 are usually predetermined, so that that the position of magnetometer 14 in relation to magnet 12 at any time can be determined based on the characteristics of the magnetic field as measured by magnetometer 14. Thus, because magnetometer 14 is secured to and deflects along with the mid-span portion of girder 102 but magnet 12 remains stationary in relation to the ground, namely the earth, as girder 102 deflects the three-dimensional deflection of the mid-span of the girder 102 in relation to the ground can be quantified in real-time based on characteristics of the magnetic field sensed by magnetometer 14.

Magnet 12 is a permanent magnet. Magnet 12 can be an electromagnet in alternative embodiments. Magnet 12 is preferably donut shaped and is preferably cast iron. However, magnet 12 can be formed from other materials, such as nickel, cobalt, and various alloys of these materials, which alloys may also include rare earth elements such as neodymium. Magnet 12 can have other shapes in alternative embodiments.

Magnetometer 14 is preferably a wireless tri-axial or three-axis magnetometer capable of measuring, in three orthogonal directions, the strength of the magnetic field to which it is subjected. Magnetometer 14 can be, for example, a Hall effect sensor, a magneto-diode, a magneto-transistor, and AMR magnetometer, a GMR magnetometer, a magnetic tunnel junction magnetometer, a magneto-optical sensor, a Lorentz force based MEMS sensor, an electron tunneling based MEMS sensor, a MEMS compass, a nuclear precision magnetic field sensor, an optically pumped magnetic field sensor, a fluxgate magnetometer, a search coil magnetic field sensor, or a SQUID magnetometer.

The magnetometer 14 is desirably configured to communicate on a wireless basis with a transceiver 16, depicted schematically in FIG. 3. Transceiver 16 is located at or near bridge 100, so that magnetometer 14 and transceiver 16 can communicate using a suitable short-range communication standard. For example, magnetometer 14 and transceiver 16 can communicate via WiFi, 2G, 3G, 4G, 5G, GPRS, EDGE, Bluetooth, ZigBee, Piconet of BLE, Zwave, or a combination of any of these; other communications protocols, including hard wire connections, can also be used.

As also depicted schematically in FIG. 3, system 10 desirably includes a gateway 18 and a computing device 20. Gateway 18 is desirably co-located with transceiver 16, and is communicatively coupled to transceiver 16. Gateway 18 desirably provides access to a wireless communication network such as the internet, and communicates with computing device 20 over such network. Gateway 18 can access the network wirelessly such as via a suitable cellular network or via a wired connection and can use any of the protocols identified above.

Gateway 18 can be configured to convert the output of transceiver 16 into a protocol, such as MQTT (MQ Telemetry Transport), suitable for facilitating the efficient transmission of data over the internet. In the alternative, gateway 18 can transmit the data using other protocols.

Computing device 20 can be, for example, a personal computer, a server, a microcontroller, a smart phone, etc. Computing device 20 is configured to determine the three-dimensional deflection of girder 102 on a real-time basis. This determination is based on the output of magnetometer 14; and the pre-determined relationship between the characteristics of the magnetic field of magnet 12 as measured by magnetometer 14, and the position of magnetometer 14 in relation to magnet 12.

Computing device 20 can optionally be configured to calculate maximum allowable vehicle weight for bridge 100 based on measured deflection of girder 102 or other structural element(s) of bridge 100. Computing device 20 can be configured to generate audible, visual, and/or electronic alarms and other types of notifications upon detecting the presence of an overweight vehicle(s); and/or when the measured deflection of girder 102 or other structural elements of bridge 100 are outside acceptable ranges. The notifications can be sent, for example, to the organization responsible for the operation or maintenance of bridge 100, via the internet or other suitable means.

In accordance with conventional edge computing paradigms, computing device 20 can be located close enough to bridge 100 to facilitate expedient routing of data between magnetometer 14 and computing device 20. Computing device 20 can be communicatively coupled to the cloud, i.e. to a remotely-located data center 22 having one or more servers or mainframe computers with greater data processing and data storage capabilities than computing device 20 alone. Computing device 20 and data center 22 preferably communicate via the internet or other suitable means. Long-term data storage can be performed at data center 22. Also, more complex and non-time-sensitive data analyses, such as trending and statistical analyses of the data, maintenance scheduling, maintenance tracking, generating maintenance notifications, etc., are desirably performed at data center 22.

Transceiver 16, gateway 18, and computing device 20 are most desirably configured to transmit and process data from more than one magnetometer 14, i.e. from additional magnetometers 14 positioned at other locations on bridge 100. Also, data center 22 can be configured to receive, process, and store data from structures in addition to bridge 100.

The specific network architecture described herein is disclosed for illustrative purposes only; other applications can incorporate different types of network architectures. For example, the processing and storage of the data generated by magnetometer 14 can be performed entirely by computing device 20, or entirely at data center 22 in alternative embodiments.

Magnetometer 14, transceiver 16, and gateway 18 are preferably powered by 120-volt alternating current provided by an electrical system associated with bridge 100. Alternatively, these components can be powered by a battery, and/or by an energy harvester such as a solar-panel array, a wind turbine, etc.

FIG. 2 depicts another application of the invention to measure deflection of road deck 110 in relation to concrete pier 108 of bridge 100. As discussed above, pier 108 is securely anchored to the ground and, along with other piers 108 located below road deck 110, supports the weight of road deck 110.

Road deck 110 and pier 108 may be separated by a bearing 114 such as that illustrated in FIG. 1. A bearing such as 114, when present, acts as the interface between road deck 110 and pier 108, and provides a resting surface between deck 110 and pier 108. Bearings such as 114 shown in FIG. 1, when present in the construction illustrated in FIG. 1, allow controlled, limited movement of road deck 110 relative to pier 108, thereby eliminating the potential for excessive structural loading that otherwise could result from a rigid connection between road deck 110 and pier 108. Thus, proper functioning of a bearing such as bearing 114 can be critical to the structural integrity of roadway 110 and pier 108, making it important to monitor the condition of bearing 114 and the adjoining structure of bridge 100.

In another exemplary application (not illustrated in FIG. 1 or 2), magnetometer 14 is securely mounted on the underside of road deck 110, directly above pier 108, so that magnetometer 14 deflects in unison with the adjacent, adjoining portion of road deck 110. Magnet 12 is securely mounted on a upper surface of pier 108, directly below magnetometer 14, so that magnetometer 14 is positioned within the magnetic field of magnet 12. The magnetic field of magnet 12 thus acts as a fixed reference frame against which the three-dimensional deflection of the portion of road deck 110 adjacent to bearing 114 can be quantified, in the manner described above in relation to girder 102.

Computing device 20 and/or the data center 22 are desirably configured to recognize specific characteristics and trends in the local deflection of road deck 110 in relation to pier 108 as an indication that a bearing such as bearing 114 is not functioning properly, i.e. as an indication that the bearing is not facilitating proper movement of road deck 110 in relation to pier 108. Computing device 20 and/or data center 22 are desirably further configured to generate an alarm or other type of audible, visible, or electronic notification, and to schedule an inspection or maintenance event upon detecting a potential issue with the functioning of bearing 114. The notifications are desirably sent, for example, to the organization responsible for the operation and maintenance of the bridge 100, via the internet or other suitable communication means.

As depicted schematically in FIG. 4, computing device 20 preferably includes a processor 30 such as a microprocessor, a memory 32 communicatively coupled to microprocessor 30, and computer executable instructions 34 stored in memory 32. Computer executable instructions 34, when executed by processor 30, cause processor 30 to perform the logical operations required in the course of automated practice of the invention. Computing device 20 also desirably includes input/output ports 36, a timer 38, and a bus for facilitating internal communications within computing device 20. Computing device 20 can also include additional components, and can have configurations other than the configuration disclosed herein.

The above-described applications of detecting and measuring structural deflections are presented for illustrative purposes only. Such systems can be used to quantify the deflection of other structural elements of bridge 100, such as girder joints and concrete joints, and are not limited to these.

Computing device 20 is desirably configured to determine useful engineering and structural parameters other than the deflection of structural members and the loading of a bridge roadway. For example, computing device 20 is most desirably configured to determine the dynamic response of a structural member to the removal of a physical load from the member. This information is used to assess integrity of structural members such as girder 102.

The selected position of magnetometer 14 in three-dimensional space is based on the characteristics, i.e. magnitude and direction, of the magnetic field of magnet 12 as measured by magnetometer 14, and a pre-determined relationship between the characteristics of the magnetic field and the location of magnetometer 14 in relation to magnet 12. The description of how the relationship between the magnetic field of magnet 12 and the position of magnetometer 14 in two-dimensional space is established is presented below, with a description of how the relationship may be established in three-dimensional space following the two dimensional space description.

FIG. 6 depicts a system 130 for obtaining the two-axis deflection measurements in a laboratory setting. System 130 includes a magnet, such as magnet 12, and a magnetometer, such as magnetometer 14. Magnet 12 is kept at a fixed reference position on a support 132 of system 130. The vertical axis of magnet 12 is designated as the “x” axis for the purposes of this disclosure. System 130 also includes a computing device, such as computing device 20 shown in FIGS. 3 and 4, communicatively coupled to magnetometer 14.

Referring further to FIG. 6, required two-axis measurements are acquired by moving magnetometer 14 into different positions on the horizontal “x-y” plane in relation to magnet 12, and recording the response of magnetometer 14 at each position. The magnetic field generated by magnet 12 at any position is designated “M_{R},” and its components along the x, y, and z axes are designated “M_{X},” M_{Y},” and “M_{Z}” respectively. Because any changes in Mₓ are substantially similar those occurring in M_{R}, the x axis is considered the axis of symmetry of magnet 12 for the purposes of this analysis.

Data relating to the magnetic field M_{R} and its components M_{X}, M_{Y}, and M_{Z} is harvested by the tri-axial magnetometer 14 as it is positioned at different locations in the x-y plane. This data is used to plot the magnetic field vector [symbol] in the x-y plane. FIG. 8 shows the magnetic field M_{R} and its relative strength at different locations in the x-y plane; and also shows the components M_{X} and M_{Y} at different locations in the x-y plane. As can be seen from FIG. 8, the characteristics of the magnetic field vary in the x-y plane in a non-random manner. Similarly to the two dimensional situation, for three-axis measurements of the magnetic field,

Mₓ=f(x,y,z)

M_{y}=f(x,y,z)

M_{z}=f(x,y,z)

The illustrated donut shape of magnet 12 in FIG. 6 facilitates substantial congruence of the “z” and “M_{Z}” directional axes as illustrated in FIG. 7A for the three dimensional case.

When the values of Mₓ, M_{y}and M_{z} are measured by magnetometer 14 at a position in three-dimensional space, solving the above three equations provides the coordinates of that position. Thus, if the function associated with each equation is known, the position of magnetometer 14 in relation to magnet 12 can be determined based on the components of the magnetic field measured by magnetometer 14.

The following method is used to establish the relationship between the magnetic field vector as measured by magnetometer 14, and the positon of magnetometer 14 in three-dimensional space. The relationship can be used to determine the position of magnetometer 14 in relation to magnet 12 based on the characteristics of the magnetic field, which in turn can be used to determine the deflection of the structural member on which magnetometer 14 is positioned.

One method in accordance with the invention is as follows: Magnet 12 is secured to a structure at a fixed reference position that does not move substantially with the load applied to the structure. Magnet 12 is doughnut-shaped, and the vertical axis of magnet 12 is designated the X axis for the purposes of this discussion. To establish the relationship between the magnetic field vector and the positon of magnetometer 14, magnet 12 is moved into different positions on the X-Y plane, and the response of magnetometer 14 is recorded at each location. It is only necessary to acquire data in the X-Y plane because the magnetic field is symmetrical about the Y-Z plane; and the following analysis can be performed using data from any cross section of the magnetic field that reflects the cylindrical symmetry of the magnetic field, i.e. from any cross-section lying in the X-Y plane.

Designating R as the unit vector of the position vector r=(x, y, z), where x, y, and z represent the positions of magnetometer 14 along the respective X, Y, and Z axes, the resultant magnetic field generated by magnet 12 at any position is M_{R}, and its components along the X, Y, and Z axes are M_{X}, M_{Y}, and M_{Z}, respectively. Because any changes in Mₓ are similar to those in M_{R} for small values of x and y, the X axis is taken as the axis of magnet 12.

The data associated with the resultant magnetic field M_{R} and its components M_{X}, M_{Y} and M_{Z}, as measured by magnetometer 14, are recorded. Based on this data, the magnetic field vector [symbol] is mapped in the X-Y plane as shown in FIG. 8.

As can be seen in FIG. 8, the magnetic field M_{R} at any position is a function of the X and Y coordinates of that position. From the nature of the magnetic field vector plot, this function can be estimated as:

$${M}_{R} = {Ae}^{- bx} {e}^{- {cy}^{2}} \qquad ( equation 1 )$$

where A, b, c are constants.

Because magnet 12 is doughnut shaped, the magnetic field is symmetric along the Y and Z axes of magnet 12. Therefore, the function of above equation (1) can be written as

$${M}_{R} = {Ae}^{- bx} {e}^{- {cy}^{2}} {e}^{- d {z}^{2}} \qquad ( equation 2 )$$

Where A, b, c, d are constants, and c=d due to the symmetry along the Y and Z axes.

To simplify calculations in three dimensions, the coordinate axes of magnet 12 can be re-oriented as shown in FIG. 9 so that in the following calculations, the X and Z coordinates are interchanged.

M_{R} is the resultant magnetic field at any position. If M_{R} is decomposed along three orthogonal axes, the resulting components are:

$$\begin{matrix}{M}_{x} = {M}_{R} sin θ cos ∅ \\ {M}_{y} = {M}_{R} sin θ sin ∅ \\ {M}_{Z} = {M}_{R} cos θ\end{matrix} \qquad ( equation 3 )$$

$$where θ = {tan}^{- 1} ( \frac{{M}_{y}}{{M}_{z}} ) and ∅ = {tan}^{- 1} ( \frac{{M}_{y}}{{M}_{x}} ) \qquad ( equation 4 )$$

Hence,

$$\begin{matrix}{M}_{x} = {Ae}^{- bz} {e}^{- {cx}^{2}} {e}^{- {dy}^{2}} sin θcos∅ \\ {M}_{y} = {Ae}^{- bz} {e}^{- {cx}^{2}} {e}^{- {dy}^{2}} sin θsin∅ \\ {M}_{z} = {Ae}^{- bz} {e}^{- {cx}^{2}} {e}^{- {dy}^{2}} cos θ\end{matrix} \qquad ( equation 5 )$$

The constants in equation set (5) can be redefined as:

$$A sin θ cos ∅ = {A}_{1} A sinθsin∅ = {A}_{2} A cos θ = {A}_{3} \qquad ( equation 6 )$$

Redefining the constants yields the following equation set:

$$\begin{matrix}{M}_{x} = {A}_{1} {e}^{- bz} {e}^{- {cx}^{2}} {e}^{- {dy}^{2}} \\ {M}_{y} = {A}_{2} {e}^{- bz} {e}^{- {cx}^{2}} {e}^{- {dy}^{2}} \\ {M}_{z} = {A}_{3} {e}^{- bz} {e}^{- {cx}^{2}} {e}^{- {dy}^{2}}\end{matrix} \qquad ( equation 7 )$$

Taking the natural logarithm of both sides of each of equations (7) yields the following equation set:

$$ln {M}_{x} = ln {A}_{1} - bz - {cx}^{2} - {dy}^{2} \\ ln {M}_{y} = ln {A}_{2} - bz - {cx}^{2} - {dy}^{2} \\ ln {M}_{z} = ln {A}_{3} - bz - {cx}^{2} - {dy}^{2} \qquad ( equations 8 )$$

As discussed above, the respective values of Mₓ, M_{y} and M_{z} at different position coordinates, i.e., at different values of x, y, and z, are measured using the magnetometer 14, and are recorded. A non-parametric regression analysis can be performed using the data set, in conjunction with equation set (8), to determine the respective values of constants A, b, c, and d.

Once the values of constants A, b, c, and d are determined, Mₓ, M_{y} and M_{z} are known as functions of x, y and z, as represented in the following equation set:

$${M}_{x} = f ( x , y , z ) \\ {M}_{y} = f ( x , y , z ) \\ {M}_{z} = f ( x , y , z ) \qquad ( equations 9 )$$

Equation set (8) can be used in the field to determine the position coordinates of the magnetometer 14 based on the values of Mₓ, M_{y}, and M_{z} measured by the magnetometer 14 at that position, i.e. the above equations can be solved for x, y, and z based on the measured values of Mₓ, M_{y}, and M_{z}. In particular, the mathematical relationship between the coordinates of magnetometer 14 and the components Mₓ, M_{y}, and M_{z} of the magnetic field of magnet 12 can stored as computer executable instructions 34 in the memory 32 of computing device 20. Magnet 12 and magnetometer 14 can be installed, for example, on bridge 100 as described above and as shown in FIGS. 1 and 2. Computer-executable instructions 34 can be configured so that, upon execution by processor 30, computer-executable instructions 34 use the above relationship to calculate the x, y, and z coordinates for a particular set of data acquired by magnetometer 14 and input to computing device 20, where each data set includes the measured components M_{X}, M_{Y}, and M_{Z} of the magnetic field vector M_{R} for that particular data point.

Computer-executable instructions 34 can be further configured to calculate the deflection of magnetometer 14, and the structural element on which magnetometer 14 is located, e.g., girder 102 of bridge 100. The deflection analysis can be performed by determining the differences between the calculated x, y, and z coordinates of a particular data set, and the respective x, y, and z coordinates of a previously-acquired data set. The previously-acquired data set can be, for example, a baseline data set acquired when no external load is being applied to the girder 102. The system 10 thus can be used, for example, to provide a real-time or near-real-time indication of the deflection of a structural element in response to an applied load. As discussed above, this information can be used, for example, to generate alarms or maintenance alerts when a particular structural limit is exceeded.

A second method in accordance with the invention is used to calculate the lateral deflection of a structural element, i.e. the deflection in a direction substantially perpendicular to the applied load, where the deflection of the structural element in the direction of the applied load is small enough to be consider negligible.

FIG. 10 depicts the magnetic field at a distance zo from the center of magnet 12 as [symbol] and the magnetic field at a displaced position dx as [symbol] . The Z direction corresponds to the direction in which an external load is applied to the structure on which magnetometer 14 is mounted.

At position (z₀), the magnetic field vector is [symbol] ,
where

$$\vert {R}_{m} \vert = \sqrt{( {M}_{x}^{2} + {M}_{y}^{2} + {M}_{z}^{2} )} \qquad ( equation 10 )$$

At a distance dx from position (z₀), the magnetic field vector is [symbol] ,
where

$$\vert {R}_{m}^{′} \vert = \sqrt{( {M}_{x}^{{′}^{2}} + {M}_{y}^{′ 2} + {M}_{z}^{{′}^{2}} )} \qquad ( equation 11 )$$

Referring to FIG. 10, it can be seen that:

$$cos θ = \frac{{\to }_{{R}_{m}^{′}} . {\to }_{{R}_{m}}}{\vert {R}_{m}^{′} \vert \vert {R}_{m} \vert} \qquad ( equation 12 )$$

Thus, because the values of [symbol] and [symbol] can be calculated, the value of cos θ can be determined.

$$Here , {\to }_{{R}_{m}^{′}} . {\to }_{{R}_{m}} = {M}_{x} . {M}_{x}^{′} + {M}_{y} . {M}_{y}^{′} + {M}_{z} . {M}_{z}^{′} \qquad ( equation 13 )$$

### Assigning

$$\frac{{R}_{m}^{′}}{{R}_{m}} = u = \frac{1}{cos θ} ,$$

and from FIG. 10,

$$dx = {z}_{0} tan θ \qquad ( equation 14 )$$

$$dx = {z}_{0} \frac{sin θ}{cos θ} \\ dx = {z}_{0} \frac{\sqrt{1 - {( cos θ )}^{2}}}{cos θ} \\ dx = {z}_{0} u \sqrt{1 - 1 / {u}^{2}} \\ dx = {{z}_{0} ( {u}^{2} - 1 )}^{1 / 2} \qquad ( equations 15 )$$

Expanding dx as a polynomial function of u yields:

$$dx = α + β u + γ {u}^{2} + δ {u}^{3} + … \qquad ( equation 16 )$$

The value of dx can be calculated by calculating the coefficients α, β, γ, . . . . As discussed above, the respective values of Mₓ, M_{y} and M_{z} at different position coordinates, i.e., at different values of x, y, and z, are measured in a calibration rig using the magnetometer 14, and are recorded. A non-parametric regression analysis is performed using the data set, in conjunction with equations (16), to determine the respective values of coefficients α, β, γ, . . . .

Once the coefficients of Equation (16) have been determined, Equations (10)-(16) can be used in a field installation, such as those shown in FIGS. 1 and 2, to determine the lateral, or X-axis deflection of the magnet 12, and the structural element on which magnetometer 14 is mounted, based on the values of Mₓ, M_{y}, and M_{z} measured by magnetometer 14 at that position, i.e., the above equations can be solved for x, y, and z based on the values of Mₓ, M_{y}, and M_{z} measured at two different times. In particular, the above equations and the noted coefficients can be stored as computer executable instructions 34 in the memory 32 of computing device 20. Computer-executable instructions 34 can be configured so that, upon execution by processor 30, computer-executable instructions 34 use the equations to determine dx, or the lateral deflection of the magnet 12 based on two sets of data acquired by magnetometer 14 and input to computing device 20, where each data set includes the components Mₓ, M_{y}, and M_{z} of the magnetic field vector M_{R} as measured at the two different times.

This methodology is based on an assumption that zo is constant, i.e. that the structural element on which magnetometer 14 is mounted undergoes no significant deflection in the direction of applied loading. Because a bridge oscillates vertically, i.e., in the z direction, in response to vehicle traffic, zo will fluctuate slightly in applications in which the technique is applied to bridges. For the purposes of this method, z₀ can be assumed constant if the maximum vertical deflection of the structural element on which the magnetometer 14 is located is much less than the distance between the magnet 12 and the magnetometer 14, e.g. where the maximum deflection is less than one-half of the spacing between the magnet 12 and the magnetometer 14. Thus, the use of this method should be reserved for applications in which the deflection of the structural element in the direction of the applied load is small enough to be considered zero.

A third method in accordance with the invention facilitates detection of the magnetic field detected by the magnetometer 14 as a function of three independent coordinates, as reflected in the following equation set:

$${M}_{x =} {f}_{x} ( x , y , z ) \\ {M}_{y} = {f}_{y} ( x , y , z ) \\ {M}_{z} = {f}_{z} ( x , y , z ) \qquad ( equations 17 )$$

Differentiating both sides of each of the above equations yields the following equation set:

$${dM}_{x} = {f}_{xx} dx + {f}_{xy} dy + {f}_{xz} dz \\ {dM}_{y} = {f}_{yx} dx + {f}_{yy} dy + {f}_{yz} dz \\ {dM}_{z} = {f}_{zx} dx + {f}_{zy} dy + {f}_{zz} dz \qquad ( equations 18 )$$

Converting equations (18) into matrix form yields the following:

$$( \begin{matrix}{dM}_{x} \\ {dM}_{y} \\ {dM}_{z}\end{matrix} ) = ( \begin{matrix}{f}_{xx} & {f}_{xy} & {f}_{xz} \\ {f}_{yx} & {f}_{yy} & {f}_{yz} \\ {f}_{zx} & {f}_{zy} & {f}_{zz}\end{matrix} ) ( \begin{matrix}dx \\ dy \\ dz\end{matrix} ) \qquad ( equations 19 )$$

Based on the above matrix:

$$[ dM ] = [ f ] [ ds ] \qquad ( equation 20 )$$

where [dM] is the column matrix that represents the magnetic field, [f] represents the function matrix and [ds] is the column matrix that represents the displacement of the magnetometer 14. Thus, using the measured magnetic field data Mₓ, M_{y}, and M_{z}, the displacement of the magnetometer 14 can be calculated using inverse matrix transformation.

$$[ ds ] = {[ f ]}^{- 1} [ dM ] \qquad ( equation 21 )$$

Like the first method discussed above, the use of this method requires knowledge of the functional forms of Mₓ, M_{y}, and M_{z}, which can be determined, for example, through the use of the technique discussed above.

Once the functional forms of Mₓ, M_{y} and M_{z} have been determined, Equation (21) can be used in a field installation, such as that shown in FIGS. 1 and 2, to determine the three-axis deflection of magnetometer 14, and the structural element on which magnetometer 14 is mounted, based on the values of the magnetic field components as measured by the magnetometer 14 at two different times, i.e. equation (21) can be solved for the values of dx, dy, and dz, based on the measured values of Mₓ, M_{y}, M_{z} at two different times. The above equations, and the functional forms of Mₓ, M_{y}, and M_{z}, can be stored as computer executable instructions 34 in memory 32 of computing device 20. Computer-executable instructions 34 can be configured so that, upon execution by processor 30, computer-executable instructions 34 use the equations to determine dx, dy, and dz for two sets of data acquired by magnetometer 14 and input to computing device 20 at two different times, where each data set includes the measured components Mₓ, M_{y}, M_{z} of the magnetic field vector M_{R} as measured at the two respective times.

In this aspect of the invention, non-parametric interpolation method is used to determine the coordinate of a magnetic field ranging between two known data points. In this method, for accuracy, a large number of data points is needed in very small intervals. The value of Mₓ, M_{y} or M_{z} are plotted in three-dimensional space and thus a surface plot is obtained. The equation of the surface is obtained via non-parametric fitting. In this method, the equation of the surface is assumed. The function of Mₓ, M_{y} or M_{z} is learned using a suitable neural network such as that illustrated in FIG. 23.

In one of its most important aspects, illustrated schematically in FIG. 22, the invention uses a combination of a system, most preferably an edge computing based IoT system, and video analytics to identify illegally loaded vehicles on a bridge and the deflection of the bridge structure resulting from those vehicles.

FIG. 15 is, as noted above, an artist's rendition of a bridge with vectors illustrating deflection of the center of the bridge, between two joints supporting the bridge structure. FIG. 15 shows such a bridge in which tri-axial deflection sensor in accordance with aspects of the invention, namely a sensor including a vibration sensor, a gyroscope, and a magnetometer, is placed on the bridge bearing or support as an aid or first step in analyzing bridge traffic density and bridge deflection resulting from vehicles passing thereover, with the deflection indicated as “A” in FIG. 15. FIG. 17, as noted above, is an illustration of a sample frame from a video feed showing moving vehicles and portions of images showing license plates of the moving vehicles, where a video feed, from which a frame such as the sample frame illustrated in FIG. 17 is used to analyze traffic patterns, traffic density, resulting damage to the bridge from an overweight vehicle that is identified using the video feed, and the like.

Considering FIGS. 15 and 17 together, in this aspect of the invention the vibration sensor portion of the inventive tri-axial deflection sensor collects time series data of vibration amplitude of the bridge center as indicated by “A” in FIG. 15. The data collected is normal 3-axis vibration measured data. Still referring to FIGS. 15 and 17, a gyroscopic sensor portion of the inventive tri-axial deflection sensor collects time series data and rate of change of angle of the deflection of the bridge, namely the angle that is opposite side “A” of the triangle illustrated in FIG. 15. Linear deflection amplitude of the bridge illustrated in FIG. 15 (and all such bridges), with such linear deflection amplitude being measured as indicated by “A” in FIG. 15, is directly proportional to the natural frequency of the bridge and the rate of change of the angle that is opposite from leg “A” of the triangle.

In this aspect of the invention, the magnetometer portion of the tri-axial sensor collects three-axis magnetic field data after a strong rare earth magnet has been placed on the bridge proximate the location indicated by “A” in FIG. 15. Any deflection of the bridge causes the distance between the magnetometer portion of the tri-axial deflection sensor and the permanent magnet to change, with the change being detected by the magnetometer portion of the tri-axial deflection sensor. The permanent magnet is preferably mounted on one of the bridge abutments, such as at the point defined by the vertex of the angle that is opposite from leg “A” of the triangle drawn in FIG. 15. In the course of practice of the invention in one of its most advantageous embodiments, the tri-axial deflection sensor data and the video surveillance data are brought together continuously on a twenty-four-hour, seven-day-a-week basis to an edge cloud server connected to a router.

Whenever the sensor data suggests or detects a triggering spike in vibration or deflection, video analytics search for the license plate number of the vehicle, the type of vehicle crossing the bridge at the same time as the timestamp on the sensor data and the video surveillance data, with this all being desirably performed in an edge cloud server. The results of this analysis are feed to a cloud server database where the results are analyzed and emailed to appropriate law enforcement authorities.

The aspect of the invention directed to performing vibration analysis to detect heavily loaded and over speed vehicles uses a sensor which includes an accelerometer measuring linear acceleration and providing as output readings of acceleration in meters per second squared in the x, y, and z, directions.

Heavy vehicles with huge momentum create impulsive forces on the bridge structure. It is like throwing pebble into a stationary water body; the ripple starts when the pebble hits the water and the ripple propagates for quite some time. In the bridge situation, the amplitude of the generated impulse wave depends on the weight of the vehicle, but the frequency response of the bridge depends mostly on the bridge structure. Frequency domain analysis reveals the natural frequency response of the bridge structure. Any change in the frequency response or abnormal dampening of the impulse wave generated by vehicles passing over the bridge reflect a fault in the form of a strain or crack of the bridge structure, which may be catastrophic if not repaired in time. Frequency domain analysis shows the natural frequencies of the bridge in Cartesian coordinates.

Amplitudes of the respective frequencies are amplified when a overweight vehicle speeds over the bridge.

In the practice of this aspect of the invention, impact analysis data desirably is observed and recorded every hour of every day. An algorithm, which preferably is resident in a “big data” server as part of an edge cloud computing operation or alternatively resides in a cloud-based “big data” server, detects impulse waves causing structural vibration where the impulse waves are caused by high speed and/or overweight vehicles crossing the bridge. The impact wave is analyzed in the frequency domain to identify excitation frequencies. The amplitude of natural frequencies and power spectral density define the alarm and threshold for speed limit and load limits of vehicles traveling over the bridge.

The sensor used in this aspect of the invention directed to performing vibration analysis to detect heavy loaded and overspeed vehicles preferably includes a sensor that not only includes an accelerometer, as discussed above, but also a gyroscope. The gyroscope measures angular velocity and provides output readings in degrees of angular velocity in three different directions, namely the x, y, and z directions, in degrees per second.

The integrity and strength of a structure is determined by the rigidity of a structure, especially for concrete structures; for metal structures integrity and strength of the structure is determined by how much force the metal structure can withstand without experiencing plastic deformation. Overloading a structure leads to plastic deformation, i.e., deformation that is permanent and the structure does not return to its original condition upon removal of the applied force. Plastic deformation may occur incrementally when the load applied to the structure is only slightly above the elastic limit of the structural material.

All of this is analyzed just by monitoring deformation, namely strain. The gyroscopic portion of the tri-axial deflection sensor of the invention provides angular velocity of the structure, which is measured reflecting structural deflection patterns.

The gyroscope of the sensor is installed at the point where maximum angular deflection in degrees per second is expected. Using the measured data the maximum linear deflection is calculated for a specific period. A mathematical model shows the relation between variance of angular velocity, which is also the rate of change in angular deflection and maximum amplitude of deflection measured in millimeters.

Here is the calculation:

A=maximum deflection at the center of two joints.

r=distance from joint to center

Let α=angular deviation

### Derivation:

For any periodic vibration we know

h(t)=A*Sin(wt)

α(t)=*Sin(wt)

w=( )=−*Cos(wt)

### Now, RMS(w)=√2=2√2

### Also, RMS(x)=√( )

### So:

$$⇒ A = \frac{√ ( ) * /}{√ 2} √ 2 ,$$

A in mm is the maximum deflection in a specified time frame.
We can also say, A □√( ), where f and r is constant.
Using the gyroscope portion of the tri-axial deflection sensor yields w in degrees per second for each of the 3 axes.
Variance (w) and A can be computed by defining a constant for the relation.

To define a constant k for the relation A=k*√( ), the system is calibrated with conventional deflection sensors and then proceeds.

The tri-axial deflection sensor used in the aspect of this invention, which is directed to performing vibration analysis in order to detect heavily loaded and overspeed vehicles on a bridge incorporates not only an accelerometer as discussed above and a gyroscope as also discussed above, but also a magnetometer. The magnetometer measures displacement, both linearly and angularly. The raw data produced by the magnetometer is angular displacement with respect to three axes, x, y, and z, with the displacement data being provided in degrees of displacement.

With influence of only the earth's magnetic field, the magnetometer shows a specific magnetic field value in each of the three axes, i.e. x, y, and z. These values are calibrated to find the angular displacement from the north or south pole of the earth's magnetic field and the change in angle due to angular deflection. However, when the magnetometer is under the influence of an ordinary magnet, the magnetometer detects the magnetic field, which is calibrated to find the distance between the magnet and the sensor. The magnetic field pattern is shown as a function of distance between the magnet and the sensor. The sensor detects relative displacement, one being static with respect to the other.

The tri-axial deflection sensor of the invention includes a strain gage having properties explained above respecting linear deflection. Strain is known and universally defined as change in length divided by total length.

With a suitably developed neural network, such as that illustrated in FIG. 23, and the scanned frames of vehicle license plates illustrated in FIGS. 17, 18, and 19, the frames are converted to gray scale images such as illustrated in FIG. 19, which are useful to remove unwanted noise from the images in order to detect number plates in larger images. A sliding window approach is used at various scales. For each window, the suitably developed neural network provides as output
(i) The probability that a license plate is present in the input image, where the image is shown in a collection of concentric boxes as in FIG. 21; and
(ii) The probability of there being a digit in each position.
   A license plate is present if the image plate falls entirely within the bounding box illustrated in FIG. 20.

In the neural network architecture according to the invention as shown in a preferred form in FIG. 23, the lower layers are preferably composed as alternating convolution and max pooling layers. However, the upper layers are fully connected and correspond to a traditional multi-layer perception neural network. The input to the first fully connected layer is the set of all features mapped at the layer below as it had been in FIG. 20. The output of the image extracts the license plate, as also depicted in FIG. 20. The detected image is then passed on through the trained network to recognize the digits and images in the license plate, all as depicted in FIGS. 18 through 21. Correlating vibration data with camera feed to detect over-speeding and heavy vehicles is preferred, namely using vibration and camera feed coupled together to detect overspeed and overweight vehicles. Cameras are installed over the vehicle travel surface of the bridge, which capture the video footage and map each license plate with the velocity of the associated vehicle. Vibration sensors installed beneath the road on the girders help analyze the vibration signatures and help detect the overweight and overspeed vehicles by correlating with the video speed, as depicted in the following diagram.

| | Normal | Overload | Over-Speed | Both |
|---|---|---|---|---|
| Video Feed | NA | NA | Alarm | Alarm |
| Vibration | NA | Alarm | Alarm | Alarm |

Although schematic implementations of present invention and at least some of its advantages are described in detail hereinabove, it should be understood that various changes, substitutions and alterations may be made to the apparatus and methods disclosed herein without departing from the spirit and scope of the invention as defined by the appended claims. The disclosed embodiments are therefore to be considered in all respects as being illustrative and not restrictive with the scope of the invention being indicated by the appended claims rather than by the foregoing description. All changes which come within the meaning and range of equivalency of the claims are therefore intended to be embraced therein. Moreover, the scope of this patent application is not intended to be limited to the particular implementations of apparatus and methods described in the specification, nor to any methods that may be described or inferentially understood by those skilled in the art to be present as described in this specification.

As disclosed above and from the foregoing description of exemplary embodiments of the invention, it will be readily apparent to those skilled in the art to which the invention pertains that the principles and particularly the compositions and methods disclosed herein can be used for applications other than those specifically mentioned. Further, as one of skill in the art will readily appreciate from the disclosure of the invention as set forth hereinabove, apparatus, methods, and steps presently existing or later developed, which perform substantially the same function or achieve substantially the same result as the corresponding embodiments described and disclosed hereinabove, may be utilized according to the description of the invention and the claims appended hereto. Accordingly, the appended claims are intended to include within their scope such apparatus, methods, and processes that provide the same result or which are, as a matter of law, embraced by the doctrine of the equivalents respecting the claims of this application.

As respecting the claims appended hereto, the term “comprising” means “including but not limited to”, whereas the term “consisting of” means “having only and no more”, and the term “consisting essentially of” means “having only and no more except for minor additions which would be known to one of skill in the art as possibly needed for operation of the invention.” The scope of the invention is, therefore, indicated by the appended claims rather than by the foregoing description and all changes which come within the range of equivalency of the claims are to be considered to be embraced within the scope of the claims. Additional objects, other advantages, and further novel features of the invention will become apparent from study of the appended claims as well as from study of the foregoing detailed discussion and description of the preferred embodiments of the invention, as that study proceeds.

The following is claimed:

1. A system for monitoring a structural element, comprising:
a) a magnetometer capable of being mounted on the structural element;
b) a magnet capable of being mounted on a surface adjacent the structural element so that the magnetometer is positioned within a magnetic field of the magnet; and
c) a computing device capable of being communicatively coupled to the magnetometer;
wherein the magnetometer is configured to measure characteristics of the magnetic field of the magnet; and the computing device is configured to determine a deflection of the structural element based on the measured characteristics of the magnetic field and a predetermined mathematical relationship between characteristics of the magnetic field and a position of the magnetometer in relation to the magnet.

2. The system of claim 1 wherein the computing device is configured to determine a position of the magnetometer in relation to the magnet in three-dimensional space based on the measured characteristics of the magnetic field and the predetermined mathematical relationship between the characteristics of the magnetic field and a position of the magnetometer in relation to the magnet.

3. The system of claim 1 wherein the measured characteristics of the magnetic field include magnitude of the magnetic field in three orthogonal directions.

4. The system of claim 1 further comprising a gateway communicatively coupled to the magnetometer and configured to transmit output of the magnetometer to the computing device over the Internet.

5. The system of claim 1 wherein the computing device comprises a memory containing information regarding the predetermined mathematical relationship between the characteristics of the magnetic field and position of the magnetometer in relation to the magnet.

6. The system of claim 2 wherein the computing device is further configured to determine deflection of the structural member by calculating a difference between a position of the structural member in relation to the magnet at a first time, and a position of the structural member in relation to the magnet at a second time.

7. The system of claim 1 wherein the computing device is further configured to determine a dynamic response of retraction from the deflection by the structural member.

8. The system of claim 6 wherein the computing device is further configured to determine the deflection of the structural member by calculating:
a) a difference between a position of the structural member in relation to a first reference axis and the magnet at the first time, and a position of the structural member in relation to the first reference axis and the magnet at the second time;
b) a difference between a position of the structural member in relation to a second reference axis and the magnet at the first time, and a position of the structural member in relation to the second reference axis and the magnet at the second time; and
c) a difference between a position of the structural member in relation to a third reference axis and the magnet at the first time, and a position of the structural member in relation to the third reference axis and the magnet at the second time; the first, second and third reference axes being orthogonal.

9. The system of claim 1 wherein the computing device is further configured to continually monitor the position of the magnetometer in relation to the magnet.

10. The system of claim 1 wherein the computing device is further configured to generate a notification when the deflection of the structural member exceeds a predetermined value.

11. The system of claim 1 wherein the computing device is a first computing device, and the system further comprises a second computing device configured to be communicatively coupled to the first computing device, and further configured to store data relating to the measured characteristics of the magnetic field and/or to perform additional processing operations on the data relating to the measured characteristics of the magnetic field.

12. The system of claim 1 wherein the surface adjacent the structural element is a surface that does not deflect substantially when the structural element is subjected to a load within the structural limitation of the structural element.

13. A method for monitoring a structural element, comprising:
a) determining a mathematical relationship between characteristics of the magnetic field and a position of the magnetometer in relation to the magnet;
b) mounting a magnetometer on the structural element;
c) mounting a magnet on a surface adjacent the structural element so that the magnetometer is positioned within a magnetic field of the magnet;
d) measuring characteristics of the magnetic field of the magnet; and
e) determining a deflection of the magnetometer in relation to the magnet based on the measured characteristics of the magnetic field and the mathematical relationship between the characteristics of the magnetic field and a position of the magnetometer in relation to the magnet.

14. The method of claim 15 wherein measuring characteristics of the magnetic field of the magnet comprises measuring characteristics of the magnetic field in three orthogonal directions.

15. The method of claim 15 wherein measuring characteristics of the magnetic field of the magnet comprises measuring a strength of the magnetic field.

16. The method of claim 15 further comprising determining a position of the magnetometer in relation to the magnet based on the measured characteristics of the magnetic field comprises and the mathematical relationship between the characteristics of the magnetic field and a position of the magnetometer in relation to the magnet.

17. The method of claim 15 wherein mounting a magnet on a surface adjacent the structural element so that the magnetometer is positioned within a magnetic field of the magnet comprises mounting the magnet on a surface that does not deflect substantially when the structural element is subjected to a load.

18. The method of claim 18 further comprising determining the deflection of the structural member when the structural member is subjected to a load by calculating a difference between a position of the magnetometer in relation to the magnet when the structural member is not subjected to the load, and a position of the magnetometer in relation to the magnet when the structural member is subjected to the load.

19. The method of claim 18 further comprising determining the deflection of the structural member by calculating a difference between a position of the structural member in relation to the magnet at a first time, and a position of the structural member in relation to the magnet at a second time.

20. The method of claim 21 further comprising determining a maximum load on a roadway supported at least in part by the structural member by measuring loads on the roadway; and
identifying the load on the roadway when the deflection of the structural member reaches a predetermined maximum value.

21. The method of claim 15 further comprising determining a dynamic response of a retraction of the deflection of the structural member.

22. The method of claim 21 wherein determining the deflection of the structural member further comprises:
a) calculating a difference between a position of the structural member in relation to a first reference axis and the magnet at the first time, and a position of the structural member in relation to the first reference axis and the magnet at the second time;
b) calculating a difference between a position of the structural member in relation to a second reference axis and the magnet at the first time, and a position of the structural member in relation to the second reference axis and the magnet at the second time; and
c) calculating a difference between a position of the structural member in relation to a third reference axis and the magnet at the first time, and a position of the structural member in relation to the third reference axis and the magnet at the second time; the first, second and third reference axes being orthogonal.

23. The method of claim 15 further comprising generating a notification when the deflection of the structural member exceeds a predetermined value.

24. The method of claim 15 wherein determining a mathematical relationship between characteristics of the magnetic field and a position of the magnetometer in relation to the magnet comprises moving the magnetometer throughout a preselected space to collect data of magnetic field strength of the magnet respecting a two-axis coordinate system.

25. The method of claim 15 wherein determining a mathematical relationship between characteristics of the magnetic field and a position of the magnetometer in relation to the magnet further comprises applying a regression analysis to the data of magnetic field strength.

26. A method for measuring structural deflection, comprising:
a) positioning a wireless magnetometer on a the portion of a structure where deflection is to be measured;
b) fixedly positioning a magnet within wireless communication range of the magnetometer and sufficiently close to the structure portion of interest that the structure portion of interest is within the magnetic field of the magnet;
c) sensing a magnetic field vector with the magnetometer as the portion of the structure deflects;
d) dynamically providing the sensed magnetic field vector position to an edge cloud computing device as the portion of the structure deflects;
e) extracting as deflection information the position of the portion of the structure for which deflection is to be measured from the dynamically provided magnetic field vector position via an algorithm executed by the edge cloud computing device, the algorithm being based on a predetermined mathematical relationship between characteristics of the magnetic field and a position of the magnetometer in relation to the magnet; and
f) transmitting the deflection information from the edge cloud computing device to a user.

27. The method of claim 28 wherein the structural deflection to be measured is vertical deflection and positioning the magnetometer and the magnet further comprises vertically aligning the magnetometer and the magnet.

28. The method of claim 29 further comprising positioning the magnet below the magnetometer.

29. A method for measuring structural deflection, consisting of:
a) positioning a wireless magnetometer on the portion of a structure where deflection is to be measured;
b) fixedly positioning a magnet within wireless communication range of the magnetometer and sufficiently close to the structure portion of interest that the structure portion of interest is within the magnetic field of the magnet;
c) sensing a magnetic field vector with the magnetometer as the portion of the structure deflects;
d) dynamically providing the sensed magnetic field vector position to an edge cloud computing device as the portion of the structure deflects;
e) extracting as deflection information the position of the portion of the structure for which deflection is to be measured from the dynamically provided magnetic field vector position via an algorithm executed by the edge cloud computing device, the algorithm being based on a predetermined mathematical relationship between characteristics of the magnetic field and a position of the magnetometer in relation to the magnet; and
f) transmitting the deflection information from the edge cloud computing device to a user.

30. The method of claim 31 wherein the structural deflection to be measured is vertical deflection and positioning the magnetometer and the magnet further comprises vertically aligning the magnetometer and the magnet.

31. The method of claim 32 further comprising positioning the magnet below the magnetometer.

32. Apparatus for detecting overweight vehicles and resulting damage to highway bridge structures therefrom, comprising:
a) a sensor for collecting dynamic vibration, gyroscopic and magnetometric data experienced by a structural member contacted by the sensor;
b) a system receiving the data from the sensor and associating the time of collection of the data therewith, the system including a data processing device for associating the time of collection of the data with the data and from the data computing deflection of the structural member at the associated time;
c) capturing images of license plates of vehicles crossing the bridge; and
d) time correlating the images of license plates of vehicles crossing the bridge with the computed deflection of the structure to identify vehicles crossing the bridge and causing structural member deflection in excess of a preselected value

33. Apparatus for detecting overweight vehicles and resulting damage to highway bridge structures therefrom, consisting of:
a) a sensor for collecting dynamic vibration, gyroscopic and magnetometric data experienced by a structural member contacted by the sensor;
b) a system receiving the data from the sensor and associating the time of collection of the data therewith, the system including a data processing device for associating the time of collection of the data with the data and from the data computing deflection of the structural member at the associated time;
c) capturing images of license plates of vehicles crossing the bridge; and
d) time correlating the images of license plates of vehicles crossing the bridge with the computed deflection of the structure to identify vehicles crossing the bridge and causing structural member deflection in excess of a preselected value
